(19) United States
(12) Patent Application Publication
(10) Pub. No.: US 2007/0113887 A1
(43) Pub. Date: May 24, 2007

(54) Material system of photovoltaic cell with micro-cavity

(76) Inventors: Lih-Hong Laih, Hsinchu Hsien (TW); Lih-Wen Laih, Hsinchu Hsien (TW); Wen-Sheng Hsieh, Taichung (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/281,451

(22) Filed: Nov. 18, 2005

(51) Int. Cl. H01L 31/00

(52) U.S. Cl. 136/259

(57) ABSTRACT

A photovoltaic cell with resonance cavity is provided. A first structure of reflection is attached toward one side of the resonance cavity and configured for reflecting light beams from the resonance cavity. The second structure of reflection is attached toward other side of the resonance cavity and configured for reflecting light beams from exterior and the resonance cavity. Thus, photos will be absorbed efficiently within the resonance cavity and converted into electrons.

### BACKGROUND OF THE INVENTION

1. Field of the Invention

The present invention relates to the material system of a photovoltaic cell, and more especially, to the material system of a solar cell.

2. Background of the Related Art

Photovoltaic cell, such as solar cell, is familiar with making use of the photovoltaic effect to convert energy from the light into electric energy. Solar radiation is composed of photons, which are particles that have a variable energy depending on the wavelength of the emissions in the solar spectrum. When the photons fall onto the surface of the semiconductor material forming a photovoltaic cell they may either be reflected, absorbed or pass through the cell.

There are certain materials that, upon absorbing this type of radiation, generate positive and negative charge couples, i.e. electrons (e−) and holes (h+), which, on being produced, move randomly through the volume of the solid and, if there is no external or internal determining factor, the opposing sign charges recombine and neutralize each other mutually. On the other hand, if a permanent electric field is created in the interior of the material, the positive and negative charges will be separated by this field, which produces a difference of potential between the two areas of material. If these two areas are interconnected by means of an external circuit, at the same time as the solar radiation falls onto the material an electric current will be produced that will run round the external circuit.

The most important parts of a solar cell are the intermediate layers made up of semiconductor or organic materials, as it is at the heart of materials of this type where the electron current and proper voltage are created. These semiconductors are specially treated to form two layers in contact with each other, which are doped differently (type p and type n) to form a positive electric field on one side and a negative one on the other side. In addition, solar cells are formed of an upper layer or mesh composed of an electrically-conductive material, which has the function of collecting the photo-generated carrier from the semiconductor and transferring them to the outer circuit and a lower layer or mesh of electrically-conductive material, which has the function of completing the electric circuit. The cells are usually connected to one another, encapsulated and mounted on a structure in the form of a carrier or frame, thereby shaping the solar panel.

As an alternative to these conventional solar modules thin-film solar cells have become known on the basis of micrometer film thicknesses. The substantial elements of a thin-film solar cell include a p/n junction structure between the absorber layer and the window layer. Unlike conventional silicon wafer wiring, thin-film cells can have integrated circuitry. Following the individual coating steps on the total surface area, the back conductor, the sandwiched cell, and the front conductor are sliced into longitudinal strips. Staggering these three slices relative to each other forms an electrical connection between cells adjoining the front and back conductor. However, the thickness of thin-film solar cells is incapable of utilizing light beams efficiently.

### SUMMARY OF THE INVENTION

In order to efficiently utilizing incident light beams, a material system for a photovoltaic cell may trap most of the incident light beams within an absorbing structure with two high-reflection layers toward the absorbing structure.

In order to enhance the photovoltaic efficiency, a material system may reflect most of light beams back to an absorbing structure.

Accordingly, one embodiment of the present invention provides a photovoltaic cell with resonance cavity. A first structure of reflection is attached toward one side of the resonance cavity and configured for reflecting light beams from the resonance cavity. The second structure of reflection is attached toward other side of the resonance cavity and configured for reflecting light beams from exterior and the resonance cavity. Thus, photos will be absorbed efficiently within the resonance cavity and converted into electrons.

### BRIEF DESCRIPTION OF THE DRAWINGS

FIG. 1 is a cross-sectional diagram illustrating the structure of material system for a photovoltaic cell in accordance with an embodiment of the present invention; and

FIG. 2 is a schematic diagram illustrating the path of the light beams in accordance with one embodiment of the present invention.

### DETAILED DESCRIPTION OF THE INVENTION

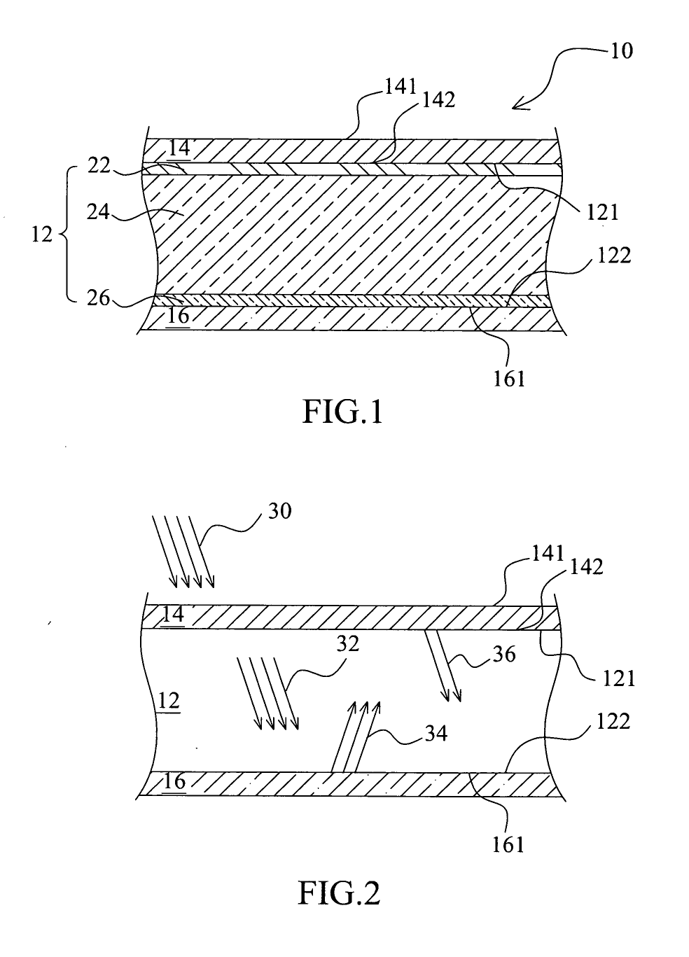

FIG. 1 is a cross-sectional diagram illustrating the structure of material system for a photovoltaic cell in accordance with an embodiment of the present invention. A material system of photovoltaic cell 10 includes an absorbing structure 12 between a first layer 14 and a second layer 16. In one embodiment, the first layer 14 is configured for receiving exterior incident light beams with one side 141 and attached to the absorbing structure 12 with the other side 142. The absorbing structure 12 is attached to the first layer 14 with one side 121 and the second layer 16 with the other side 122. The second layer 16 is configured for both reflecting light beams from the absorbing structure 12 and attached to the absorbing structure 12 with one side 161. The material system of photovoltaic cell 10 may include other structures, for example, a layer of window glass (not shown) is on the first layer 14 and a substrate (not shown) attached to the second layer 16.

In one embodiment, the absorbing structure 12 configured for absorbing photons may include an absorber layer 24 between a layer of front conductor 22 and a layer of back conductor 26. The layer of front conductor 22 is attached to the first layer 14 with the side 121 and the layer of back conductor 26 is attached to the second layer 16 with the side 122. The layer of front conductor 22 and the layer of back conductor 26 are made of semiconductor material doped differently, for example, type p and type n, to form a positive electric field on one side and a negative one on the other. On the other hand, the layer of front conductor 22 and the layer of back conductor 26 are placed in contact with each other by way of the absorber layer 24. The absorber layer 24 is made of, not limited to, single or poly-crystalline or silicon-based material. Alternatively, the absorber layer 24 may be made of semiconductor compound, such as GaAs, CdS or CuInSe₂, etc.

Next, the first layer 14 may have an anti-reflection coating (AR coating) at the side 141 to capable of receiving exterior incident light beams. Furthermore, the surface of the side 141 may be modified, such as roughening, for the help of trapping the light beams. On the other hand, the first layer 14 further have a high-reflection coating (HR coating) (i.e. reflectivity >99.8%) at the side 142. On the other hand, the first layer 14 may further have a plurality of layers of different refractive index between the side 141 and the side 142. In one embodiment, the plurality of refractive index increases from the side 141 to the side 142 for sure that exterior incident light beams successfully enter into the absorbing structure 12.

Furthermore, the second layer 16 is configured for reflecting the light beams back to the absorbing structure 12. In one embodiment, the second layer 16, one or more layers, may be made of metal or alloy material, such as aluminum (Al) or silver, etc. Alternatively, the second layer 16 may be made of Distributed Bragg Reflector (DBR), such as SiO₂/TiO₂, AlAs/GaAs, etc.. Alternatively, the second layer 16 may be made of those materials aforementioned to be formed the structure of hybrid materials. It is noted that the layer of back conductor may be introduced into the second layer 16 on the condition of semiconductor or conductive materials.

On application, shown in FIG. 2, exterior light beams 30 penetrate into the absorbing structure 12 through the side 141 of the first layer 14. The portion of incident light beams is absorbed by the absorbing structure 12 and the other portion 32 reach onto the side 161 of the second layer 16. The second layer 16 according to the spirit of the present invention is advantageous to utilizing of the portion not being absorbed. The second layer 16 may reflect the portion of light beams 34 back to the absorbing structure 12. On the other hand, the light beams through the absorbing structure 12 are still reflected by the first layer 14 when reaching to the side 121 of the absorbing structure 12. The first layer 14 provided with the HR coating of the side 142 is also advantageous to reutilizing of the portion of light beams. Accordingly, the association of the first layer 14 and the second layer 16 may trap the light beams 36 into the absorbing structure 12 and cause micro-resonance cavity in the absorbing structure 12. Thus, photo resonance will be formed within the absorbing structure 12 to enhance photovoltaic efficiency.

Accordingly, a material system of photovoltaic cell includes an absorbing structure between a first and a second layers. The absorbing structure is provided with a first side and a second side. The first layer is attached to said first side, configured for accepting light beams from exterior with a third side and reflecting light beams from the absorbing structure with a fourth side. The second layer is attached to the second side and configured for reflecting light beams from the absorbing structure. Photo resonance is implemented within the absorbing structure by the first layer associated with the second layer.

Accordingly, a material system of photovoltaic cell includes an absorbing structure between a first and a second layers. The absorbing structure is with a first side and a second side. The first layer is attached to said first side, configured for accepting light beams from exterior with a third side and reflecting light beams from the absorbing structure with a fourth side. The second layer is attached to the second side and configured for reflecting light beams from the absorbing structure. Photo resonance is implemented within the absorbing structure by way of the first layer associated with the second layer.

Although the present invention has been explained in relation to its preferred embodiment, it is to be understood that other modifications and variation can be made without departing the spirit and scope of the invention as hereafter claimed.

What is claimed is:

1. A material system of photovoltaic cell, comprising:
an absorbing structure with a first side and a second side;
a first layer attached to said first side, wherein said first layer is configured for receiving light beams from exterior with a third side and reflecting light beams from said absorbing structure with a fourth side; and
a second layer attached to said second side and configured for reflecting light beams from said absorbing structure, wherein photo resonance is implemented within said absorbing structure by way of said first layer associated with said second layer.

2. The material system of photovoltaic cell according to claim 1, wherein said absorbing structure comprises a layer of front conductor, an absorber layer and a layer of back conductor.

3. The material system of photovoltaic cell according to claim 2, wherein said first side is provided by said layer of front conductor and said second side is provided by said layer of back conductor.

4. The material system of photovoltaic cell according to claim 2, wherein said absorber layer is made of crystalline silicon-based material.

5. The material system of photovoltaic cell according to claim 2, wherein said absorber layer is made of amorphous silicon-based material.

6. The material system of photovoltaic cell according to claim 2, wherein said absorber layer is made of semiconductor compound.

7. The material system of photovoltaic cell according to claim 2, wherein said layer of front conductor and said layer of back conductor are made of semiconductor materials being doped differently each other.

8. The material system of photovoltaic cell according to claim 1, wherein said first layer comprises an anti-reflection coating at said third side.

9. The material system of photovoltaic cell according to claim 1, wherein said first layer comprises a plurality of layers of different reflectivity.

10. The material system of photovoltaic cell according to claim 9, wherein said first layer have a plurality of reflectivity increased from said third side to fourth side.

11. The material system of photovoltaic cell according to claim 1, wherein said first layer comprises a high-reflection coating (HR coating) at said fourth side, and said high-reflection coating has a reflectivity substantial in excess of 99.8%.

12. The material system of photovoltaic cell according to claim 1, wherein said second layer is made of metal material.

13. The material system of photovoltaic cell according to claim 1, wherein said second layer is made of alloy materials.

14. The material system of photovoltaic cell according to claim 1, wherein said second layer is made of dielectric material of Distributed Bragg Reflector (DBR).

15. The material system of photovoltaic cell according to claim 1, wherein said second layer is made of semiconductor materials.

16. The material system of photovoltaic cell according to claim 1, wherein said second layer is made of the materials selected from the groups consisted of metal, alloy, dielectric material, insulating material, semiconductor material and the combination of thereof.

17. A photovoltaic cell with resonance cavity, comprising:
a resonance cavity;
a first structure of reflection attached to one side of said resonance cavity and configured for reflecting light beams from said resonance cavity; and
a second structure of reflection attached to other side of said resonance cavity and configured for reflecting light beams from exterior and said resonance cavity.

18. The photovoltaic cell with resonance cavity according to claim 17, wherein said first structure of reflection is further configured for receiving light beams from exterior.

19. The photovoltaic cell with resonance cavity according to claim 17, wherein said first structure of reflection comprises an anti-reflection (AR) coating attached to said resonance cavity.

20. The photovoltaic cell with resonance cavity according to claim 17, wherein said second structure of reflection is made of the material selected from the group consisted of metal, alloy, dielectric material, semiconductor material and the combination of thereof.
